(19) United States
(12) Patent Application Publication
(10) Pub. No.: US 2023/0035123 A1
(43) Pub. Date: Feb. 2, 2023

(54) SENSOR CHIP WITH A PLURALITY OF INTEGRATED SENSOR CIRCUITS

(71) Applicant: Infineon Technologies AG, Neubiberg (DE)

(72) Inventors: Stephan LEISENHEIMER, Deisenhofen (DE); Richard HEINZ, Muenchen (DE); Hans-Joerg WAGNER, Villach (AT); Markus KAMMERSBERGER, Lendorf (AT)

(73) Assignee: Infineon Technologies AG, Neubiberg (DE)

(21) Appl. No.: 17/875,933

(22) Filed: Jul. 28, 2022

(30) Foreign Application Priority Data
Aug. 2, 2021 (DE) 102021120054.7

(51) Int. Cl. B81B 7/00; B81C 1/00

(52) U.S. Cl. CPC B81B 7/008; B81C 1/00246; B81C 1/00865; B81B 2207/03

(57) ABSTRACT

The present disclosure relates to a sensor chip, including a semiconductor substrate, a first sensor circuit monolithically integrated into the semiconductor substrate, at least one second sensor circuit monolithically integrated into the semiconductor substrate, wherein the first and second integrated sensor circuits are embodied identically.

### FIELD

The present disclosure is concerned generally with integrated sensor circuits and in particular with sensor chips comprising more than one integrated sensor circuit (sensor IC).

### BACKGROUND

If a plurality of sensors are required for a measurement, the measurement accuracy improves in most cases if the individual sensors match as much as possible, that is to say are structurally identical. By way of example, in the case of a measurement of a differential magnetic field in regard to stray field robustness an accuracy of the measurement results depends on a matching accuracy or structural homogeneity of the two sensors. The two redundant sensors are usually implemented by means of a dedicated chip in each case.

There is therefore a need for a further increase in the matching accuracy of at least two sensors.

### SUMMARY

This need is taken into account by devices and methods having features of the independent patent claims. The dependent patent claims relate to advantageous developments.

In accordance with a first aspect, the present disclosure proposes a sensor chip including a semiconductor substrate, a first sensor circuit monolithically integrated into or onto the semiconductor substrate, and at least one second sensor circuit monolithically integrated into or onto the semiconductor substrate. In this case, the first and second integrated sensor circuits are embodied identically. In other words, a sensor chip including at least two sensor circuits which are embodied identically, but operate independently, on a common sensor chip (die) is proposed. As necessary, three, four or more sensor circuits on one chip are also conceivable.

In accordance with some exemplary embodiments, the first and second integrated sensor circuits are arranged laterally adjacently on the common semiconductor substrate (for example silicon). That arises for example as a result of the production of the integrated sensor circuits by means of conventional CMOS processes (CMOS=Complementary metal-oxide-semiconductor).

In accordance with some exemplary embodiments, the semiconductor substrate, the first integrated sensor circuit and the second integrated sensor circuit are embodied integrally (monolithically). In this regard, the sensor circuits can for example be positioned very close to one another on the semiconductor substrate.

In accordance with some exemplary embodiments, the first and second integrated sensor circuits form redundant sensors. They are thus suitable for measuring one and the same physical variable independently of one another.

In accordance with some exemplary embodiments, a common chip package for encapsulating the first and second integrated sensor circuits integrated jointly on the semiconductor substrate is present. The die with the at least two integrated sensor circuits can thus be packaged by means of a single chip package.

In accordance with some exemplary embodiments, the chip package is embodied as a plastic package.

In accordance with some exemplary embodiments, the chip package is embodied as a wafer level ball grid array (WLB) package. A ball grid array (BGA) is a package form of integrated circuits in which the connections for SMD placement (SMD=Surface-mounted device) lie compactly on the underside of the device. Wafer level hall grid array technology is distinguished by the fact that all required processing steps for the package are carried out on the wafer. This allows production of extremely small and flat packages having excellent electrical and thermal properties in conjunction with particularly low production costs.

In accordance with some exemplary embodiments, the first and second integrated sensor circuits in each case include sensor circuits from the set of magnetic sensor circuits, radar sensor circuits, MEMS sensor circuits for providing respective sensor signals.

In accordance with some exemplary embodiments, the first and second integrated sensor circuits in each case include an evaluation circuit for sensor signals measured by means of sensor elements. In accordance with some exemplary embodiments, the first integrated sensor circuit includes a first amplifier and/or comparator circuit monolithically integrated with a first sensor on a common semiconductor substrate. The second integrated sensor circuit includes a second amplifier and/or comparator circuit monolithically integrated with a second sensor on the common semiconductor substrate. The respective amplifier and/or comparator circuits can include circuit components, such as e.g., signal amplifiers, operational amplifiers, logic gates, transistors, etc. The sensors (e.g., in a Wheatstone bridge arrangement) can thus be monolithically integrated together with a respective amplifier and/or comparator circuit on a die, as a result of which the redundant sensor chip can be embodied in a very small or space-saving and highly accurate fashion. Furthermore, the sensors can also be monolithically integrated together with respective ADCs and/or respective power supplies (Power Management Units, PMU) on a die.

In accordance with some exemplary embodiments, the first integrated sensor circuit and the second integrated sensor circuit are galvanically isolated from one another. The first integrated sensor circuit and the second integrated sensor circuit can thus have different reference potentials. By way of example, isolating decoupling trenches can be provided between the first and second integrated sensor circuits in the semiconductor substrate. Disturbances for example when transferring measurement signals can thus be avoided.

In accordance with some exemplary embodiments, a plurality of identical integrated sensor circuits in a two-dimensional matrix arrangement are integrated into the semiconductor substrate. That is appropriate, for example, if more than two integrated sensor circuits are intended to be integrated into the semiconductor substrate.

In accordance with a further aspect, the present disclosure proposes a method for producing a sensor chip. The method includes providing a semiconductor wafer, integrating a plurality of identical integrated sensor circuit structures on the semiconductor wafer, and subdividing the semiconductor wafer into a plurality of dies, wherein a die includes at least two identical integrated sensor circuit structures.

In accordance with some exemplary embodiments, the method furthermore includes packaging the respective dies in a respective chip package for encapsulating the sensor circuit structures integrated in each case jointly on the die.

In accordance with some exemplary embodiments, the packaging is effected in accordance with a wafer level packaging method.

In accordance with some exemplary embodiments, the subdividing includes singulating the plurality of dies.

In accordance with some exemplary embodiments, the respectively identical integrated sensor circuit structures in each case include sensor circuits from the set of magnetic sensor circuits, radar sensor circuits, MEMS sensor circuits for providing sensor signals.

Exemplary embodiments make it possible to create a sensor array from an existing sensor layout by way of modified singulating. The matching factor between the sensor cells is very good in this case since a monolithic approach is involved. There is no need to develop a new sensor. Consequently, money and time can be saved and the flexibility can be increased. Exemplary embodiments are also of interest for redundant sensors in which two independent sensors are situated in a monolithic chip. This has the advantage of redundancy plus very good matching and a small form factor.

### BRIEF DESCRIPTION OF THE DRAWINGS

Some examples of devices and/or methods are explained in greater detail merely by way of example below with reference to the accompanying figures, in which:

FIG. 1 shows a schematic flow diagram of a method for producing a sensor chip with a plurality of identical integrated sensor circuits in accordance with one exemplary embodiment of the present disclosure;

FIG. 2 shows a wafer with a multiplicity of identical integrated sensor circuits;

FIG. 3 shows different numbers of monolithically integrated sensor circuits on a die;

FIG. 4 shows a sensor chip in accordance with one exemplary embodiment; and

FIG. 5 shows one exemplary embodiment of a redundant xMR sensor with two integrated sensor circuits on a die.

### DETAILED DESCRIPTION

Some examples will now be described more thoroughly with reference to the accompanying figures. However, further possible examples are not restricted to the features of these embodiments described in detail. These may have modifications of the features and counterparts and alternatives to the features. Furthermore, the terminology used herein for describing specific examples is not intended to be limiting for further possible examples.

Throughout the description of the figures, identical or similar reference signs refer to identical or similar elements or features which can be implemented in each case identically or else in modified form, while they provide the same or a similar function. In the figures, furthermore, the thicknesses of lines, layers and/or regions may be exaggerated for elucidation purposes.

If two elements A and B are combined using an “or”, this should be understood such that all possible combinations are disclosed, i.e., only A, only B, and A and B, unless expressly defined otherwise in an individual case. As alternative wording for the same combinations, it is possible to use “at least one from A and B” or “A and/or B”. That applies equivalently to combinations of more than two elements.

If a singular form, e.g., “a, an” and “the”, is used and the use of only a single element is defined neither explicitly nor implicitly as obligatory, further examples can also use a plurality of elements in order to implement the same function. If a function is described below as being implemented using a plurality of elements, further examples can implement the same function using a single element or a single processing entity. Furthermore, it goes without saying that the terms “comprises”, “comprising”, “has” and/or “having” in their usage describe the presence of the specified features, integers, steps, operations, processes, elements, components and/or a group thereof, but do not exclude the presence or the addition of one or more other features, integers, steps, operations, processes, elements, components and/or a group thereof.

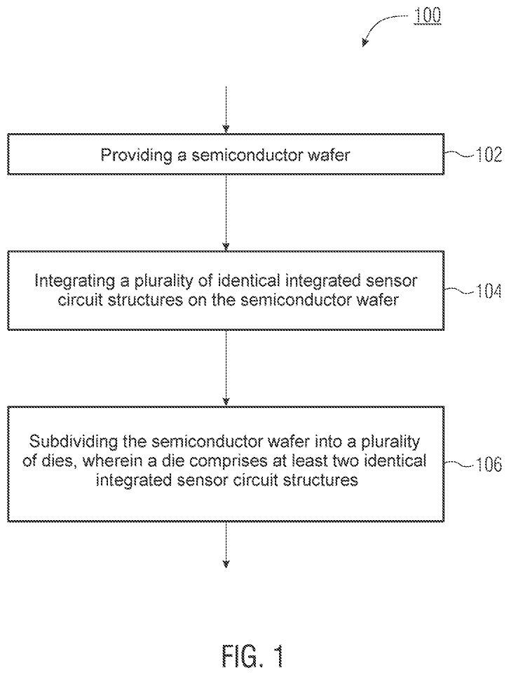

FIG. 1 shows a schematic flow diagram of a method 100 for producing a sensor chip in accordance with one exemplary embodiment of the present disclosure.

The method 100 comprises a step 102 of providing a semiconductor wafer, a step 104 of integrating a plurality of identical integrated sensor circuit structures on the semiconductor wafer, and a step 106 of subdividing the semiconductor wafer into a plurality of dies, wherein each die has at least two identical integrated sensor circuit structures.

The semiconductor wafer can be produced from mono- or polycrystalline (semiconductor) blanks, so-called ingots, and serve as a semiconductor substrate (for example monocrystalline silicon) for the plurality of identical integrated sensor circuit structures. Integrated sensor circuit structures are taken to mean identical integrated sensor circuits on the semiconductor wafer. In this case, an integrated sensor circuit comprises at least one sensor element integrated into or onto the semiconductor substrate, such as, for example, a lateral or vertical Hall sensor element, a magnetoresistive resistance element, a radar sensor element, etc. Sensor elements can optionally be arranged in Wheatstone half-bridges or full-bridges on the semiconductor substrate. Besides the actual sensor elements, each of the identical integrated sensor circuits can also comprise further integrated circuit elements, such as e.g., analog-to-digital converters (ADCs), amplifiers, comparators and/or power management units (PMUs).

Consequently, hundreds, thousands or millions of identical sensor circuits (sensor ICs) monolithically integrated into the semiconductor substrate can be present in the assemblage on the semiconductor wafer. Conventionally, each sensor IC on a die is singulated for further processing. That means that each individual sensor circuit is detached from the wafer assemblage and then potted in a chip package. In principle, many different package forms are possible for this, such as, for example, plastic or WLB packages.

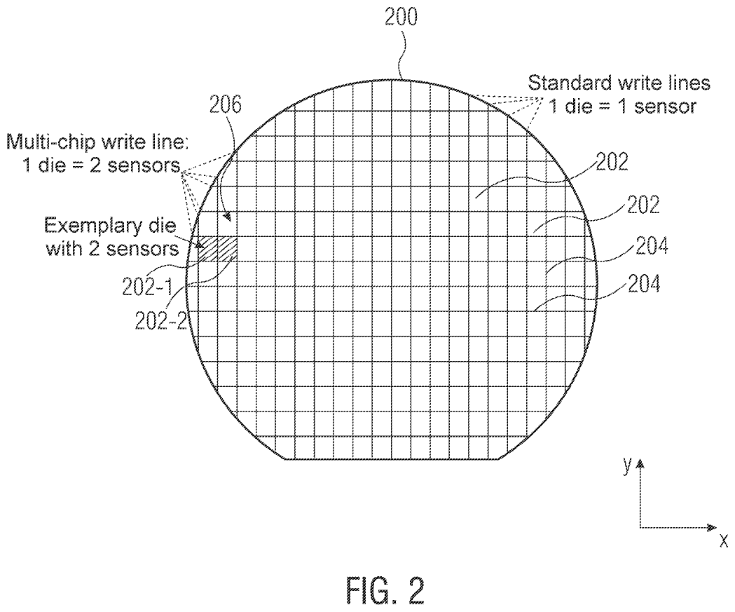

The present disclosure now proposes, however, not individually detaching each sensor circuit, but rather detaching dies having in each case at least two sensor circuits monolithically integrated into the semiconductor substrate from the semiconductor wafer. This is illustrated schematically in FIG. 2.

FIG. 2 shows a semiconductor wafer 200 with a multiplicity of identical sensor ICs 202 integrated on the wafer 200. The individual sensor ICs 202 are indicated by respective rectangles. Edges 204 of the rectangles denote conventional dicing lines for so-called wafer dicing. Conventional methods for dicing the wafers include wafer scribing using a diamond tip. The latter can be guided under slight pressure over scribing regions (dicing lines 204) and a minimal depression can thus be produced. This gives rise to desired defects and stresses in the crystal lattice of the wafers, which then break at the scribed location under small loads. However, the thicker the wafer 200 becomes, the more difficult it becomes to carry out wafer scribing using diamond. Furthermore, untidy edges arise as a result of the scribing and subsequent breaking of the wafers and make it more difficult to grip the individual chips during further processing. In the case of dicing by sawing, diamond-tipped cutting disks can be guided along the dicing lines 204. Since silicon dust arises in this method, the wafers subsequently have to be cleaned by way of rinsing liquids. Wafer scribing using a laser can eliminate these problems. Even thick wafers can be diced easily and with exact edges 204.

Irrespective of which of the wafer dicing principles mentioned above is used, it is proposed to singulate the wafer 200 into a plurality of dies in such a way that each die comprises at least two identical integrated sensor ICs 202. One such exemplary die having two identical sensor ICs 202-1, 202-2 that are adjacent in the x-direction is identified by reference sign 206 in FIG. 2. This can be achieved for example by the wafer 200 being scribed, sawn or subjected to laser treatment only along every second dicing line 204 in the x-direction. In the y-direction, in the case of the exemplary (2×1) setup, dicing can be effected along every dicing line 204.

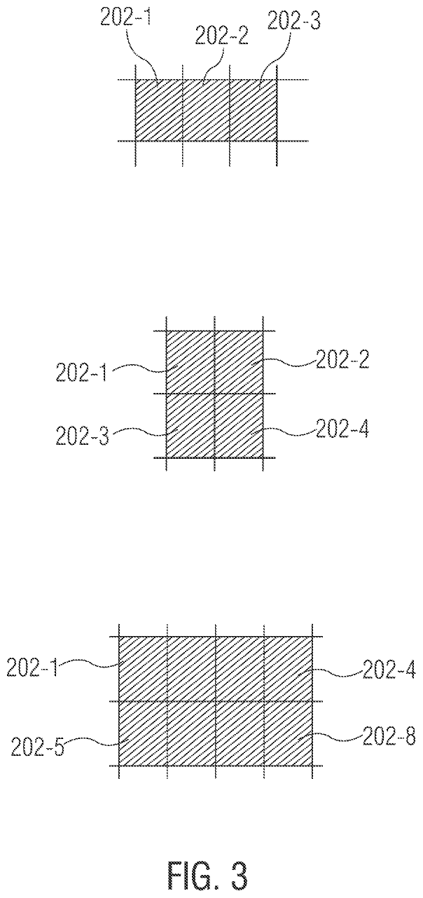

It will be immediately apparent to the person skilled in the art that sensor chips having more than two sensor ICs 202 can also be provided in this way. In this respect, FIG. 3 (top) shows by way of example sensor chips having three identical sensor ICs 202-1, 202-2, 202-3 that are adjacent in the x-direction on a die, having four identical sensor ICs 202-1, 202-2, 202-3, 202,4 arranged in a 2×2 matrix on a die (FIG. 3, middle), or eight identical sensor ICs arranged in a 4×2 matrix on a die (FIG. 3, bottom).

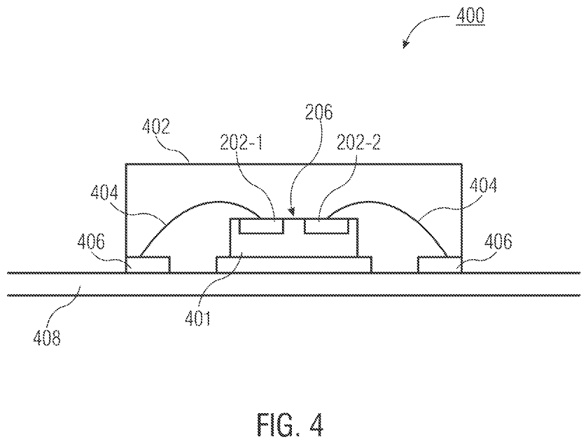

The multi-sensor IC dies thus produced, including their electrical connection locations, can then be encapsulated in each case by a chip package, or package. This can give rise in each case to a WLB package, for example. One resultant exemplary embodiment of a sensor chip 400 is shown in FIG. 4.

The sensor chip 400 comprises a first sensor circuit 202-1 monolithically integrated onto or into a semiconductor substrate or die 401, and a second sensor circuit 202-2, monolithically integrated into the semiconductor substrate 401. The first and second integrated sensor circuits are embodied identically and can thus be used as redundant sensors, for example. The sensor chip 400 furthermore comprises a chip package 402 for encapsulating the first and second integrated sensor circuits 202-1, 202-2 integrated jointly on the semiconductor substrate 401. The chip package 402 can be embodied as a plastic or WLB package. The sensor circuits 202-1, 202-2 are coupled to connection pads 406 of the chip package 402 by way of respective bond wires 404. The sensor chip 400 or the chip package 402 is coupled to connections of a printed circuit board 408 by way of the connection pads 406.

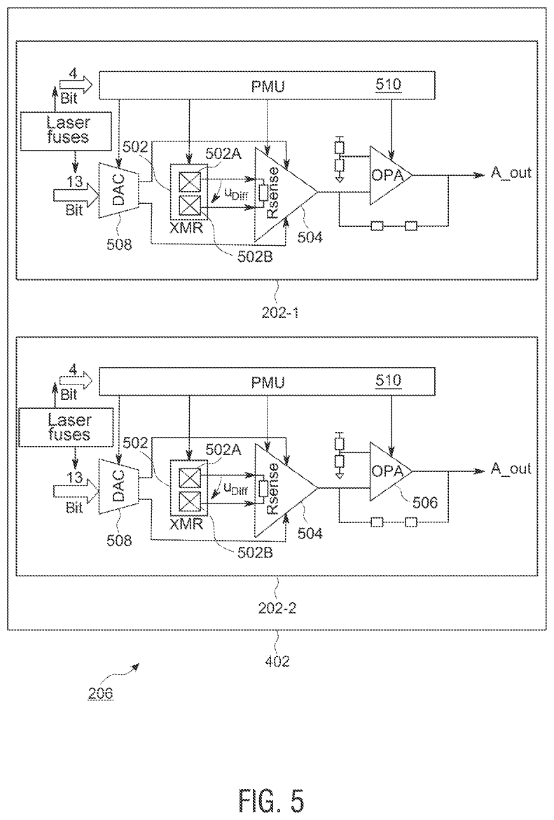

In one exemplary embodiment concerning magnetoresistive sensors (xMR sensors), besides xMR resistance elements or full-bridges realized by means of xMR layer stacks, the integrated sensor circuits 202-1, 202-1 can additionally comprise further monolithically integrated circuit components. In this respect, FIG. 5 shows one exemplary embodiment of a redundant magnetic sensor chip 206 comprising a first integrated sensor circuit 202-1 and a second integrated sensor circuit 202-2. In this case, the first and second integrated sensor circuits 202-1, 202-2 are arranged on a common die and in a common semiconductor or chip package 402 on a common die 401. Advantageously, they are galvanically isolated from one another, such that they cannot adversely affect one another and they can yield reliable measurement signals that are independent of one another.

Each of the integrated sensor circuits 202-1, 202-2 shown in FIG. 5 comprises an integrated (Wheatstone) bridge circuit 502 having four xMR resistance elements arranged in two half-bridges 502A, 502B for providing a respective differential measurement signal (differential measurement voltage) U_{Diff}. Hall elements are likewise possible. Each of the integrated sensor circuits 202-1, 202-2 furthermore comprises a differential amplifier circuit 504 monolithically integrated with the respective bridge circuit 502 on a common semiconductor substrate, said differential amplifier circuit being configured to amplify the respective measurement signal (differential measurement voltage) U_{Diff}. A differential input of the differential amplifier 504 is thus coupled to a differential output of the bridge circuit 502. The differential amplifier 504 provides an amplified measurement signal at its output. The first integrated sensor circuit 202-1 can thus comprise a first amplifier 504 integrated with the first xMR sensor 502 on a common die. Equally, the second integrated sensor circuit 202-2 can comprise a second amplifier 504 integrated with the second xMR sensor 502 on a common die.

The output of the respective differential amplifier 504 is coupled to a first input of a respective operational amplifier 506, which provides a respective analog output signal Aₒᵤₜ at its output. The respective operational amplifier 506 can be integrated together with the respective bridge circuit 502 and the respective differential amplifier 504 on a common die by means of a CMOS process. The respective differential amplifier 504 can be calibrated (offset, temperature) by way of a respective digital-to-analog converter 508. The respective digital-to-analog converter 508 can be integrated together with the respective bridge circuit 502, the respective differential amplifier 504 and/or the respective operational amplifier 506 on a common die by means of a CMOS process and thus form the respective integrated sensor circuit 202-1, 202-2. All of the integrated circuit components can be supplied with electrical supply energy by way of a respective power supply unit 510. The respective power supply unit 510 can likewise be integrated together with the respective xMR bridge circuit 502 on the common die.

Exemplary embodiments of the present disclosure with a plurality of sensor ICs on a die may be relevant to stray-field-robust xMR or Hall sensors, redundant architectures for functional safety, or to sensor arrays for complex position detection requirements.

The aspects and features that have been described in association with a specific one of the examples above can also be combined with one or more of the further examples in order to replace an identical or similar feature of this further example or in order additionally to introduce the feature into the further example.

It furthermore goes without saying that the disclosure of a plurality of steps, processes, operations or functions disclosed in the description or the claims should not be interpreted as being mandatorily in the order described, unless this is explicitly indicated or absolutely necessary for technical reasons in an individual case. Therefore, the preceding description does not limit the implementation of a plurality of steps or functions to a specific order. Furthermore, in further examples, an individual step, an individual function, an individual process or an individual operation can include a plurality of partial steps, partial functions, partial processes or partial operations and/or be subdivided into them.

When some aspects in the preceding sections have been described in association with a device or a system, these aspects should also be understood as a description of the corresponding method. In this case, for example, a block, a device or a functional aspect of the device or of the system can correspond to a feature, for instance a method step, of the corresponding method. Analogously thereto, aspects described in association with a method should also be understood as a description of a corresponding block, a corresponding element, a property or a functional feature of a corresponding device or a corresponding system.

The claims that follow are hereby incorporated in the detailed description, where each claim can be representative of a separate example by itself. Furthermore, it should be taken into consideration that—although a dependent claim refers in the claims to a specific combination with one or more other claims—other examples can also encompass a combination of the dependent claim with the subject matter of any other dependent or independent claim. Such combinations are hereby explicitly proposed, provided that in an individual case no indication is given that a specific combination is not intended. Furthermore, features of a claim are also intended to be included for any other independent claim, even if this claim is not directly defined as being dependent on this other independent claim.

1. A sensor chip, comprising:
a semiconductor substrate;
a first sensor circuit monolithically integrated into the semiconductor substrate; and
at least one second sensor circuit monolithically integrated into the semiconductor substrate, wherein the first and the second integrated sensor circuits are embodied identically.

2. The sensor chip as claimed in claim 1, wherein the first and the second integrated sensor circuits are arranged laterally adjacently on the semiconductor substrate.

3. The sensor chip as claimed in claim 1, wherein the semiconductor substrate, the first integrated sensor circuit and the second integrated sensor circuit are embodied integrally.

4. The sensor chip as claimed in claim 1, wherein the first and the second integrated sensor circuits are redundant sensors.

5. The sensor chip as claimed in claim 1, further comprising
a common chip package that encapsulates the first and the second integrated sensor circuits integrated jointly on the semiconductor substrate.

6. The sensor chip as claimed in claim 5, wherein the chip package is embodied as a wafer level ball grid array package.

7. The sensor chip as claimed in claim 1, wherein each of the first and the second integrated sensor circuits comprise sensor circuits from the set of magnetic sensor circuits, radar sensor circuits, and MEMS sensor circuits for providing sensor signals.

8. The sensor chip as claimed in claim 1, wherein each of the first and the second integrated sensor circuits comprise an evaluation circuit for evaluating sensor signals.

9. The sensor chip as claimed in claim 1, wherein a plurality of identical integrated sensor circuits in a two-dimensional matrix arrangement are integrated into the semiconductor substrate of the sensor chip.

10. A method for producing a sensor chip, the method comprising:
providing a semiconductor wafer;
integrating a plurality of identical integrated sensor circuit structures on the semiconductor wafer; and
subdividing the semiconductor wafer into a plurality of dies, wherein each die comprises at least two identical integrated sensor circuit structures.

11. The method as claimed in claim 10, further comprising:
packaging each of the plurality of dies in a respective chip package that encapsulates the at least two identical integrated sensor circuit structures integrated in each case jointly on the die.

12. The method as claimed in claim 11, wherein the packaging is effected in accordance with a wafer level packaging method.

13. The method as claimed in claim 10, wherein subdividing comprises singulating the plurality of dies.

14. The method as claimed in claim 10, wherein the at least two identical integrated sensor circuit structures of each die comprise sensor circuits from the set of magnetic sensor circuits, radar sensor circuits, and MEMS sensor circuits for providing sensor signals.
